(19) United States
(12) Patent Application Publication
(10) Pub. No.: US 2021/0210416 A1
(43) Pub. Date: Jul. 8, 2021

(54) METHOD FOR PRODUCING A SUBSTRATE PLATE, SUBSTRATE PLATE, METHOD FOR PRODUCING A SEMICONDUCTOR MODULE AND SEMICONDUCTOR MODULE

(71) Applicant: Heraeus Deutschland GmbH & Co. KG, Hanau (DE)

(72) Inventor: Ronald EISELE, Surendorf (DE)

(73) Assignee: Heraeus Deutschland GmbH & Co. KG, Hanau (DE)

(21) Appl. No.: 15/999,689

(22) PCT Filed: Feb. 9, 2017
(86) PCT No.: PCT/EP2017/052881

§ 371 Date: Aug. 20, 2018

(51) Int. Cl. H01L 23/492; H01L 21/48; H01L 23/00

(52) U.S. Cl. CPC H01L 23/4924; H01L 2924/15763; H01L 24/32; H01L 2224/32245; H01L 2924/01047; H01L 2924/01079; H01L 2924/01029; H01L 2924/01028; H01L 2924/01402; H01L 2924/01403; H01L 2924/01026; H01L 2924/01027; H01L 2924/01074; H01L 2924/01042; H01L 2924/1203; H01L 2924/1301; H01L 2924/15738; H01L 2924/15747; H01L 21/4871

(57) ABSTRACT

One aspect relates to a method for producing a substrate plate for a large-area semiconductor element, particularly for a thyristor wafer or a diode. At least one first layer made from a first material, with a first coefficient of expansion, and at least one second layer made from a second material of low expandability, with a second coefficient of expansion, which is smaller than the first coefficient of expansion, are bonded to one another by means of a low-temperature sintering method at a bonding temperature of 150° C.-300° C. At least one first bonding layer made from a bonding material is formed between the first layer and the second layer and the bonding temperature substantially corresponds to the mounting temperature during the bonding of the substrate plate produced with at least one large-area semiconductor element.

The invention relates to a method for producing a substrate plate for a large-area semiconductor element, particularly for a thyristor wafer or a diode. Furthermore, the invention relates to a substrate plate for a large-area semiconductor element, particularly for a thyristor wafer or a diode. In addition, the invention relates to a method for producing a semiconductor module and a semiconductor module.

Vertical power-electronics semiconductor elements, such as thyristors or diodes are preferably applied individually onto circuit carriers of low thermal expandability, which must be highly conductive both electrically and thermally. In addition, the thermal expansions of the semiconductor element, which is 2.5 to 3 ppm/K in the case of silicon for example, and the conductive circuit carrier must be adapted. To this end, the difference between the coefficient of thermal expansion of the semiconductor element and the coefficient of thermal expansion of the circuit carrier must be kept as low as possible, in order to keep the mechanical stresses between the semiconductor element and the circuit carrier as low as possible.

It is known to use so-called substrate plates made from molybdenum for semiconductor elements. Molybdenum has a relatively low thermal expansion on the one hand and good thermal conductivity on the other hand. However, molybdenum has a specific electrical resistance approximately three-times higher than that of copper. In addition, molybdenum is a relatively expensive material.

Copper-tungsten alloys (CuW), copper-molybdenum alloys (CuMo) and Cu—Mo—Cu plating exist for example. These result in thermal expansions of between 8 ppm/K and 12 ppm/K.

CuW and CuMo alloys and Cu—Mo—Cu plating are technologically complicated to produce and exceptionally expensive. In particular, owing to the high melting-point difference between copper and the alloy constituents tungsten and molybdenum, alloy formation requires exceptionally comprehensive method steps until alloying is successful. In addition, the thermal conductivity of the pure copper is greatly reduced by alloy formation.

The plating of copper and molybdenum must be carried out at very high temperatures, for example at temperatures of 600° C. to 800° C., to promote the bond-forming diffusion. During this high-temperature process, the destructive oxidation of the copper material must be prevented by means of cost-intensive measures.

A further disadvantage of the diffusion-annealed layer sequence is the strong deformation and distortion following cooling from the diffusion temperature to room temperature or operating temperature of the semiconductor element which is connected to the substrate plate. In order to produce flat substrate plates, the same must be stretch rolled in rolling stocks. As a result, the diffusion layer is mechanically destroyed to some extent. An asymmetrically coated sequence of copper layers and molybdenum layers cannot be realized by diffusion annealing for this reason.

Starting from this prior art, it is the object of the present invention to specify a method for producing a substrate plate for a large-area semiconductor element, particularly for a thyristor wafer or a diode, which is exceptionally simple and inexpensive to carry out and with the aid of which an optimized substrate plate can be produced.

Furthermore, it is the object of the present invention to specify a substrate plate for a large-area semiconductor element, which has exceptionally low expandability and is inexpensive at the same time.

Furthermore, it is an object of the present invention to specify a method for producing a semiconductor module. Furthermore, it is the object of the present invention to specify a developed semiconductor module, wherein the semiconductor module has exceptionally low expandability and is constructed to be highly electrically conductive.

According to the invention, the object is achieved, with a view to the method for producing a substrate plate for a large-area semiconductor element, by means of the subject matter of claim 1, with a view to the substrate plate for a large-area semiconductor element, by means of the subject matter of claim 6, with a view to the method for producing a semiconductor module, comprising a substrate plate and at least one large-area semiconductor element, by means of the subject matter of claim 16, and with a view to the semiconductor module, comprising a substrate plate and at least one large-area semiconductor element, by means of the subject matter of claim 19.

The invention is based on the idea of specifying a method for producing a substrate plate for a large-area semiconductor element, wherein at least one first layer made from a first material with a first coefficient of expansion and at least one second layer made from a second material of low expandability with a second coefficient of expansion, which is smaller than the first coefficient of expansion, are bonded to one another at a bonding temperature of 150° C. to 300° C. The bonding of the first copper layer first layer made from a first material to the second layer made from a second material particularly preferably takes place by means of a low-temperature sintering method.

According to the invention, at least one first bonding layer made from a bonding material is additionally formed between the first layer and the second layer.

The bonding temperature essentially corresponds to the mounting temperature during the bonding of the substrate plate produced to at least one large-area semiconductor element. The large-area semiconductor element may be a thyristor wafer or a diode. The large-area semiconductor element is particularly preferably a silicon semiconductor wafer.

In one embodiment of the method according to the invention, the bonding temperature may be 200° C. to 280° C., particularly 220° C. to 270° C., particularly 240° C. to 260° C., particularly 250° C.

The bonding material of the bonding layer can preferably produce a bond, which withstands temperatures above the bonding temperature. The bonding material preferably has a diffusion metal, particularly silver (Ag) and/or a silver alloy and/or gold (Au) and/or a gold alloy and/or copper (Cu) and/or a copper alloy.

The second material of low expandability with the second coefficient of expansion at least of the second layer preferably has a nickel alloy, particularly Invar (Fe₆₅Ni₃₅) or Invar 36 (Fe₆₄Ni₃₆) or Kovar (Fe₅₄Ni₂₉Co₁₇), and/or tungsten (W) and/or an iron-nickel-cobalt alloy (FeNiCo alloy). Molybdenum (Mo) or a molybdenum alloy has proven itself as a particularly preferred material with regards to the second material of at least the second layer.

In principle, all metals which have a smaller coefficient of expansion than the metal of the first material can be used as second materials. Insofar as the first material is copper or a copper alloy, or the first layer consists of copper or a copper alloy, all metals which have a lower coefficient of expansion than copper are suitable as second material.

The lower the coefficient of expansion of the second material is and at the same time the higher the thermal conductivity of the second material is, the better suited this material is as second material. The electrical conductivity is physically connected to the thermal conductivity. Therefore, all metals which have a good thermal and/or electrical conductivity and a low thermal expansion are well-suited to being used as second material or being included by the second material.

In Column 6, the following table shows the coefficient of expansion of the material listed in Column 1. All materials which correspondingly have a smaller coefficient of expansion than copper are consequently suited to serving as second material or being used as second material.

| | | | 4) | 5) | 6) | | 8) | 9) |
|---|---|---|---|---|---|---|---|---|
| | 2) | 3) | Temp. | Th. C. | Coeff. | 7) | El. Cond. | Temp. |
| 1) | Density | M. E. | Deg. | cal/cm | of exp. | Sp. ht. | m/ohm | coeff. |
| Material | kg/dm³ | kp/mm² | Celsius | secdeg | m/mdeg | cal/gdeg | mm² | 1/deg |
| Silver | 10.49 | 8160 | 960 | 1.00 | 19.7 | 0.056 | 63 | 4.10 |
| Copper | 8.96 | 12500 | 1083 | 0.94 | 16.2 | 0.092 | 60 | 4.31 |
| Iron | 7.87 | 21550 | 1530 | 0.18 | 11.7 | 0.11 | 10.3 | 6.57 |
| Grey cast | 7.20 | 8000-13000 | 1150-1300 | 0.13 | 9.0 | 0.13 | 1-2 | |
| iron | | | | | | | | |
| Molybdenum | 10.2 | 33630 | 2625 | 0.35 | 5 | 0.061 | 19.4 | 4.73 |
| Monel | 8.58 | 15900 | 1320-1350 | 0.06 | 14 | 0.12 | 1.6 | 0.19 |
| metal | | | | | | | | |
| Nickel | 8.90 | 19700 | 1455 | 0.22 | 13.3 | 0.105 | 14.6 | 6.75 |
| Niobium | 8.57 | 16000 | 2415 | | 7.0 | 0.0065 | 7.7 | |
| Osmium | 22.5 | 57000 | 2700 | | 4.6 | 0.031 | 10.4 | 4.45 |
| Platinum | 21.45 | 17320 | 1774 | 0.17 | 8.9 | 6.032 | 10.2 | 3.92 |
| C15 steel | 7.85 | 20800 | 1510 | 0.12 | 11.1 | 0.11 | 9.3 | 5.7 |
| C35 steel | 7.84 | 20600 | 1490 | 0.12 | 11.1 | 0.11 | 8.6 | 5.2 |
| C60 steel | 7.83 | 20400 | 1470 | 0.11 | 11.1 | 0.11 | 7.9 | 4.7 |
| 41Cr4 | 7.84 | 20700 | 1490 | 0.1 | 11.0 | 0.11 | 8.0 | |
| X10Cr13 | 7.75 | 22000 | 1500 | 0.065 | 10.0 | 0.11 | 1.7 | |
| 36% Ni | 8.13 | 14500 | 1450 | 0.025 | 0.9 | 0.123 | | |
| steel | | | | | | | | |
| Tantalum | 16.6 | 18820 | 3000 | 0.13 | 6.6 | 0.036 | 8.1 | 3.47 |
| Titanium | 4.54 | 10520 | 1800 | 0.041 | 10.8 | 0.126 | 1.25 | 5.46 |
| Vanadium | 6.0 | 15000 | 1735 | | 8.5 | 0.12 | 3.84 | |
| Bismuth | 9.8 | 3480 | 271 | 0.020 | 12.4 | 0.034 | 0.94 | 4.45 |
| Tungsten | 19.3 | 41530 | 3380 | 0.48 | 4.5 | 0.032 | 18.2 | 4.82 |
| Zirconium | 6.5 | 6970 | 1850 | | 10 | 0.066 | 2.44 | 4.4 |

1) Material (or symbol)
2) Density
3) Modulus of elasticity
4) Melting temperature
5) Thermal conductivity (10 + 3*alpha)
6) Linear coefficient of expansion (10 + 6*alpha)
7) Spec. heat
8) Electrical conductivity
9) Temperature coefficient of the electrical resistance

The bonding at least of the first layer at least to the second layer and the bonding layer can take place by means of the application of pressure, particularly using a pressure of 5 MPa-30 MPa, particularly of 10 MPa-28 MPa, particularly of 25 MPa.

A low-temperature sintering which is preferably to be carried out for bonding at least the first and at least the second layer and the at least one bonding layer preferably takes place at temperatures of 150° C.-300° C. and at an applied pressure of 5 MPa-30 MPa. Particularly preferably, the low-temperature sintering is carried out at a temperature of 250° C. and a pressure of 25 MPa, wherein the sintering is preferably carried out for from 1 to 10 min., for example 4 min.

The bonding temperature in the method for producing a substrate plate essentially corresponds to the mounting temperature in the bonding of the substrate plate produced to at least one large-area semiconductor element. The bonding temperature may correspond exactly to the mounting temperature. Furthermore, it is possible that the bonding temperature deviates by at most 20%, in particular at most 15%, in particular at most 10%, in particular at most 5%, from the mounting temperature. The percentual calculation of the deviation of the bonding temperature from the mounting temperature takes place on the basis of a calculation of the difference between the bonding temperature in Kelvin and the mounting temperature in Kelvin.

In addition to carrying out a low-temperature sintering method, it is in addition possible to bond the individual layers of the substrate plate to one another by means of diffusion soldering with the formation of high-melting intermetallic phases. The use of adhesives for bonding the individual layers of the substrate plate is also possible.

Preferably, the bonding material is introduced as a sinter material or constituent of the sinter material between at least the first layer and at least the second layer. A composition which can be sintered to form a conductive layer can consequently be used for producing a sintered bond between the layers to be bonded. The composition, which can still be sintered, may have the use type of an ink, a paste or a sinter preform in the form of a layered pressed item. Sinter preforms are created by means of the application and drying of metal pastes or metal sinter pastes. Sinter preforms of this type can still be sintered. Alternatively, it is possible that the bonding material is formed as a film, particularly as a metal film, and this film, particularly metal film, is arranged between the first layer and the second layer.

It is possible that the sinter paste, which comprises the bonding material or consists of the bonding material, is applied onto the first layer and/or the second layer by means of printing, particularly screen or stencil printing. Optionally, the sinter paste or metal sinter paste can be dried before carrying out the actual sintering method. Without passing through the fluid state, the metal particles of the sinter paste are bonded during sintering by means of diffusion with the formation of a solid electric-current and heat conductive metallic bond or metal bond between at least the first and second layer. A sinter paste is particularly preferably used when bonding at least the first and at least the second layer, which paste comprises silver and/or a silver alloy and/or silver carbonate and/or silver oxide.

In a further embodiment of the invention, it is possible that a layer, for example applied by electroplating or sputtering, is applied onto at least the first and/or second layer, preferably onto the second layer, before the application of a bonding layer, for better bonding of the bonding layer or joining layer. Insofar as the second layer is a molybdenum layer or the second material of the second layer comprises molybdenum, a nickel-silver layer (NiAg layer) can be applied by electroplating onto the side to be bonded of the second layer. The bonding material, silver in particular, can adhere on this nickel-silver layer particularly well.

The invention is furthermore based in a coordinate aspect on the idea of specifying a substrate plate for a large-area semiconductor element, particularly for a thyristor wafer or a diode, wherein the substrate plate is preferably produced using an aforementioned method according to the invention.

The substrate plate according to the invention comprises:
at least one first layer made from a first material with a first coefficient of expansion, and
at least one second layer made from a second material of low expandability with a second coefficient of expansion, which is smaller than the first coefficient of expansion,
wherein at least one first bonding layer is formed between the first layer and the second layer, which first bonding layer comprises diffusion metal, particularly silver (Ag) and/or a silver alloy and/or gold (Au) and/or a gold alloy and/or copper (Cu) and/or a copper alloy.

The first material preferably has metal or consists of metal. In particular, the first material has copper or a copper alloy or the first material is copper or a copper alloy. The second material, can particularly have a nickel alloy, particularly Invar (Fe₆₅Ni₃₅) or Invar 36 (Fe₆₄Ni₃₆) or Kovar (Fe₅₄Ni₂₉Co₁₇), and/or tungsten (W) and/or an iron-nickel-cobalt alloy (FeNiCo alloy). The second material is preferably a nickel alloy, particularly Invar (Fe₆₅Ni₃₅) or Invar 36 (Fe₆₄Ni₃₆) or Kovar (Fe₅₄Ni₂₉Co₁₇), and/or tungsten (W) and/or an iron-nickel-cobalt alloy (FeNiCo alloy).

In a particularly preferred embodiment of the invention, the second material comprises molybdenum (Mo) or the second material is molybdenum (Mo). It is also conceivable that the second material comprises a molybdenum alloy or is a molybdenum alloy.

At least the first bonding layer can be formed as a boundary layer of the first layer and/or the second layer.

It is possible that the bonding layer is a self-contained visible layer. If the bonding material is only applied with a low layer thickness during the production of the substrate plate according to the invention, the bonding layer in the product produced, namely in the substrate plate produced, can be formed as a boundary layer of the first layer and/or the second layer. The bonding material can for example be diffused into the first layer and/or the second layer at least in certain sections.

Particularly preferably, the bonding material of the bonding layer is silver or a silver alloy, so that the silver or the silver alloy is diffused into the first layer and/or the second layer in certain sections during formation of the bonding layer as boundary layer.

In a further embodiment of the invention, the substrate plate has at least one third layer, wherein the third layer consists of a/the first material. The third layer is preferably bonded to the second layer, made from the second material of low expandability, by means of a second bonding layer made from a/the bonding material. Consequently, the substrate plate can comprise three layers which are bonded to one another with the aid of two bonding layers.

In a further embodiment of the invention, the substrate plate can have at least one fourth layer which is formed from a/the second material. The fourth layer is preferably bonded to the third layer made from a/the first material by means of a third bonding layer made from a/the bonding material. In this embodiment of the invention, the substrate plate comprises four layers, which are either formed from the first material or from the second material, wherein these four layers are bonded to one another by means of at least three bonding layers.

The substrate plate can have a symmetrical arrangement of the individual layers and bonding layer(s). The symmetrical arrangement of the individual layers and bonding layer(s) is preferably formed in such a manner that a flat substrate plate is formed. A symmetrical arrangement of the individual layers is to be understood such that in the case of a theoretical formation of an axis of symmetry through the substrate plate, a symmetrical arrangement of the individual layers and bonding layer(s) with consistent materials and layer thicknesses is formed both above and below the axis of symmetry. The axis of symmetry halves the arrangement of the individual layers with respect to the total thickness of the substrate plate, wherein the total thickness of the substrate plate is formed by adding the individual layer thicknesses.

When forming a symmetrical arrangement of the individual layers and bonding layer(s), it is possible to form a flat substrate plate.

In an alternative embodiment of the invention, it is possible that the individual layers and bonding layer(s) of the substrate plate are arranged asymmetrically. The individual layers and bonding layer(s) are in particular arranged asymmetrically such that initially a convexly or concavely shaped substrate plate is formed. The substrate plate preferably has a controlled convex or concave shape. In other words, the maximum curvature is defined.

An asymmetrical arrangement can be seen by means of a theoretically formed axis of symmetry. The axis of symmetry halves the total thickness of the arrangement of the individual layers, wherein the total thickness is defined by adding the individual layer thicknesses of the substrate plate. The curvature or the convex or concave shape of the substrate plate is preferably controlled by arranging and/or forming the second layer and/or the fourth layer made from a/the second material, namely a/the material of low expandability. The second layer and/or at least the fourth layer is or are formed asymmetrically in relation to the total arrangement of all layers and bonding layer(s), so that an axis of symmetry is created in a targeted manner from the expansion of the substrate plate produced.

Depending on the use case, by means of the position and/or formation of the second layer and/or at least the fourth layer made from a second material of low expandability, a curved substrate plate contour can be created after final cooling. To this end, the substrate plate according to the invention is produced with the aid of the previously mentioned method according to the invention and connected with the subsequently mentioned method according to the invention for producing a semiconductor module with a large-area semiconductor element.

The layers of the substrate plate can have different layer thicknesses in order to achieve an asymmetric arrangement. It is possible that the first layer and the second layer have different layer thicknesses. In addition, it is possible that the first layer, the second layer and the third layer have different layer thicknesses.

In a further embodiment of the invention, the second layer and/or the fourth layer can be embedded in a layer made from the first material. The layer made from the first material can be the first layer and/or the third layer.

In a further embodiment of the invention, the second layer and/or the fourth layer is or are formed in a frame-like and/or grid-like and/or wire-like manner. Preferably, this formation of the second layer and/or the fourth layer takes place in combination with the embedding of the respective layer in a layer made from the first material.

A reduction of the thermal expansion of the substrate plate is for example achieved by means of a combination according to the invention of a copper layer or copper-alloy layer with one or more molybdenum layers. An increasing ratio of the molybdenum proportion to the copper proportion of the thickness of the substrate plate reduces the resultant total expansion. A layer ratio of 2 thickness portions of copper/copper alloy to 1 thickness portion of molybdenum/molybdenum alloy results in a thermal expansion of approx. 8-9 ppm/K. The thickness ratios of all layers made from the first material to all layers made from the second material is preferably 2:1.

A low Young's modulus of a copper used compared to the high Young's modulus of the molybdenum (330 GPa at 20° C.) leads to proportionately smaller molybdenum portions of the total thickness of the substrate plate. For example, the Young's modulus of the copper of a first layer and/or at least a third layer is 60 GPa. A Young's modulus of this type is achieved by soft annealing for more than four hours subject to exposure to nitrogen (N₂).

The invention is furthermore based on the idea of specifying a method for producing a semiconductor module, which comprises at least one substrate plate and at least one large-area semiconductor element. Preferably, the substrate plate is a previously mentioned substrate plate according to the invention or a substrate plate which was produced using a previously mentioned method according to the invention. The large-area semiconductor element is a thyristor wafer or a diode in particular. The large-area semiconductor element is particularly preferably a silicon semiconductor wafer.

The method according to the invention for producing a semiconductor module is based on the fact that the semiconductor element is bonded by means of a contacting layer to the substrate plate at a mounting temperature of 150° C. to 300° C., wherein the mounting temperature substantially corresponds to the bonding temperature during the bonding of the layers of the substrate plate. In other words, the mounting temperature during the bonding of the semiconductor element to the substrate plate substantially corresponds to the bonding temperature acting during the production of the substrate plate. The mounting temperature may correspond exactly to the bonding temperature. Preferably, the mounting temperature deviates by at most 20%, in particular at most 15%, in particular at most 10%, in particular at most 5%, from the bonding temperature. The percentual calculation of the deviation of the mounting temperature from the bonding temperature takes place on the basis of a calculation of the difference between the mounting temperature in Kelvin and the bonding temperature in Kelvin.

The mounting temperature may be 200° C. to 280° C., in particular 220° C. to 270° C., in particular 240° C. to 260° C., in particular 250° C.

The large-area semiconductor element is preferably applied onto the surface of the substrate plate or bonded to the surface of the substrate plate, wherein the surface is formed by a layer, particularly the first layer or third layer, which consists of a first material. The surface can also be termed the uppermost side of the substrate plate.

The contacting layer may for example be a sinter paste. It is also possible that the contacting layer is an adhesive layer or a solder layer.

In an embodiment of the invention, the bonding of the layers of the substrate plate and the bonding of the substrate plate to the large-area semiconductor element can take place simultaneously. In this embodiment, all layers, bonding layer(s) and the large-area semiconductor element are arranged above one another and for example bonded to one another by means of a low-temperature sintering method at the same time.

By combining the method according to the invention for producing a substrate plate with the method according to the invention for producing a semiconductor module, it is possible to produce a flat semiconductor module with asymmetric arrangement of the layers and bonding layer(s) of the substrate plate. The individual layer and bonding layer(s) of the substrate plate are arranged asymmetrically to one another. The asymmetry can be controlled by means of the number of layers and/or by means of the layer thicknesses.

For example, it is possible to produce a substrate plate from a copper layer and a molybdenum layer. Here, the two layers may have different layer thicknesses. In addition, a Cu—Mo—Mo—Cu—Cu layer sequence is conceivable. Here, there is consequently an asymmetric number of layers and an asymmetric layer sequence.

The asymmetric arrangement of layers and bonding layer(s) is interconnected at a bonding temperature which substantially corresponds to the mounting temperature of the substrate plate with the large-area semiconductor element.

The asymmetric layer sequence initially leads to a curved deformation of the substrate plate after cooling. The bonding of the large-area semiconductor element to the substrate plate follows. Here, it can be seen that the curved deformation or the concave or convex deformation degrades during the reheating of the asymmetric substrate plate produced. Following the bonding of the substrate plate to the large-area semiconductor element, the semiconductor module produced or the substrate plate assumes a temperature-stable final shape in a new stress equilibrium in a manner which meets the requirements.

The invention is furthermore based according to a coordinate aspect on the idea of specifying a semiconductor module, wherein the semiconductor module is preferably produced using a previously mentioned method according to the invention. The semiconductor module comprises a substrate plate and at least one large-area semiconductor element. The substrate plate is a substrate plate according to the invention or a substrate plate which is produced by means of a previously mentioned method according to the invention.

The large-area semiconductor element is a thyristor wafer or a diode in particular. The large-area semiconductor element is particularly preferably a silicon semiconductor wafer. The large-area semiconductor element preferably has an area which is only slightly smaller than the base area of the substrate plate.

The semiconductor element is bonded to the first layer of the substrate plate by means of a contacting layer in particular. The contacting layer may be a sinter layer or an electrically conductive adhesive layer or a solder layer. The first layer is a layer made from a first material. This first material is preferably copper or a copper alloy.

The invention is explained in more detail in the following with further details and with reference to the attached schematic drawings on the basis of exemplary embodiments. In the figures:

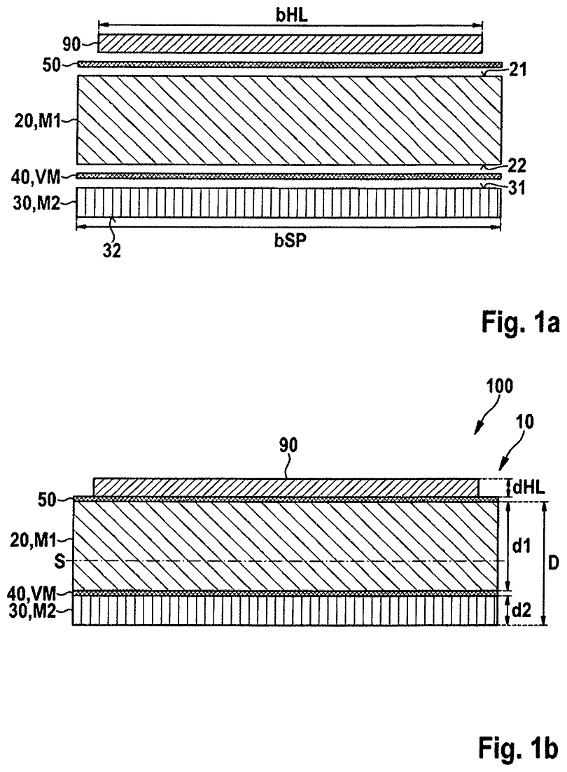

FIG. 1a shows the arrangement of individual layers and components of a semiconductor module according to the invention according to a first exemplary embodiment;

FIG. 1b shows the semiconductor module according to FIG. 1a in the bonded state;

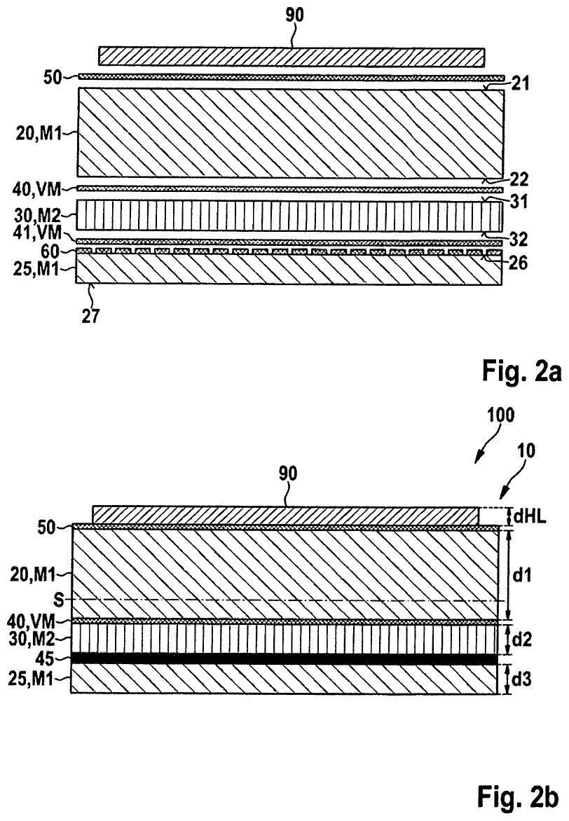

FIG. 2a shows the arrangement of individual layers and components of a semiconductor module according to the invention according to a second embodiment; and

FIG. 2b shows the semiconductor module according to FIG. 2a in the bonded state.

In the following, the same reference numerals are used for the same parts and parts with the same action.

The individual layers and components of a semiconductor module 100 (see FIG. 1b) to be produced are illustrated in FIG. 1a. The semiconductor module 100 consists of the large-area semiconductor element 90 and the substrate plate 10. The substrate plate 10 comprises a first layer 20 made from a first material M1 and a second layer 30 made from a second material M2. The material M1 is preferably metal, particularly copper or a copper alloy. The material M2 is by contrast a material of low expandability with a second coefficient of expansion, which is lower than the first coefficient of expansion of the first material M1. The second material M2 may be a nickel alloy, particularly Invar or Invar 36 or Kovar and/or tungsten and/or an iron-nickel-cobalt alloy. In the present exemplary embodiment, the material M2 is molybdenum. A first bonding layer 40 made from a bonding material VM is formed between the first layer 20 and the second layer 30. The bonding material VM of the bonding layer 40 creates a bond between the first layer 20 and the second layer 30, which withstands temperatures above a bonding temperature. The bonding layer preferably has diffusion metal, particularly silver and/or a silver alloy and/or gold and/or a gold alloy and/or copper and/or a copper alloy.

The bonding layer is preferably formed as a sinter layer, particularly as a sinter paste. This sinter paste, which preferably has one of the listed diffusion metals, particularly silver and/or a silver alloy and/or silver carbonate and/or silver oxide, can for example be applied by means of a printing method onto the second side 22 of the first layer 20 and/or onto the first side 31 of the second layer 30. In the bonded state of the substrate plate 10, the first side 21 of the first layer 20 faces the large-area semiconductor element 90. The second side 22 of the first layer 20 faces the second layer 30 by contrast. In the bonded state, the first side 31 of the second layer 30 faces the first layer 20. The second side 32 of the second layer 30 is by contrast formed facing away from the first layer 20. The layer thickness d1 of the first layer 20 is at least twice as large as the layer thickness d2 of the second layer 30. Preferably, the layer thickness d1 is between 0.2 mm and 3.0 mm, whereas the layer thickness d2 is between 0.1 mm and 2.0 mm. The thickness of the first bonding layer 40 is preferably between 1 μm and 50 μm.

With the aid of the axis of symmetry S drawn in FIG. 1b it becomes clear that the structure of the substrate plate 10 is an asymmetrical structure of the individual layers 20, 30 and 40. The axis of symmetry S halves the total thickness D of the substrate plate 10. The total thickness D is formed by means of the addition of the layer thicknesses d1 and d2 and the layer thickness of the first bonding layer 40. With the aid of a substrate plate 10 which is asymmetric in this manner, a flat semiconductor module 100 in particular can be produced.

In the example illustrated, the large-area semiconductor element 90 is a silicon semiconductor formed as a thyristor. The width bHL of the semiconductor element 90 is only slightly smaller than the width bSP of the substrate plate. In the example illustrated, the large-area semiconductor element 90 is bonded to the substrate plate 10 by means of a contacting layer 50. The contacting layer 50 may in principle be an adhesive layer, a sinter-paste layer or a solder layer. In the present case, all layers 20, 30 and 40 are bonded to the large-area semiconductor element 90 and the contacting layer 50 simultaneously, so that the contacting layer 50 is preferably formed equivalently to the first bonding layer 40. The first bonding layer 40 and the contacting layer 50 are preferably a sinter paste.

Preferably, the layers 20, 30, 40, 50 and the large-area semiconductor element 90 are bonded to one another by means of a low-temperature sintering method at a bonding temperature of 150° C. to 300° C. The bonding temperature is particularly preferably 250° C.

The bonding of the layers 20, 30, 40, 50 to the large-area semiconductor element 90 preferably takes place by means of the application of pressure, particularly at a pressure of 5 MPa to 30 MPa, particularly of 10 MPa to 28 MPa, particularly of 25 MPa.

Alternatively, the large-area semiconductor element 90 can be applied to a previously produced substrate plate 10 in a separate mounting step. To this end, the large-area semiconductor element 90 is applied onto the first side 21 of the first layer 20 of the substrate plate 10 with the aid of the contacting layer 50. The surface 21 of the substrate plate 10 to be bonded to the semiconductor element is the first side 21 of the first layer 20.

To bond the large-area semiconductor element 90 to a previously produced substrate plate 10, the arrangement is loaded with a mounting temperature of 150° C. to 300° C., wherein this mounting temperature substantially corresponds to the bonding temperature during the bonding of the layers 20, 30 and 40 of the substrate plate 10.

A second embodiment with regards to a semiconductor module 100 to be produced (cf. FIG. 2b) is illustrated in FIGS. 2a and 2b. This is likewise an asymmetric structure of the substrate plate 10.

The substrate plate 10 consists of a first layer 20, a second layer 30 and a third layer 25. The first layer 20 and the third layer 25 have a first material M1. The material is preferably copper. A second layer 30 made from the second material M2 is formed between these two layers 20 and 25, which have different layer thicknesses d1 and d3. The second material M2 consists of a material of low expandability or the coefficient of expansion of the second material M2 is lower than the coefficient of expansion of the first material M1. The second material M2 is preferably molybdenum.

The indicated axis of symmetry S shows that the substrate plate 10 according to FIG. 2a or 2b is also an asymmetric structure of the same. A first bonding layer 40 is formed between the first layer 20 and the second layer 30. This bonding layer 40 is preferably a sinter layer, which has a bonding material VM, preferably silver. A second bonding layer 41 is formed between the second layer 30 and the third layer 25. This bonding layer 41 is preferably likewise a sinter layer, which has a bonding material VM, namely silver.

An adhesion-improving layer 60 is preferably applied on the first side 26 of the third layer 25 (cf. FIG. 2a). The first side 26 of the third layer 25 is the side of the third layer 25 facing the second layer 30. The adhesion-improving layer 60 is preferably electroplated onto the third layer 25. The adhesion-improving layer 60 is a silver layer for example. The adhesion between the third layer 25 and the second bonding layer 41 can be improved with the aid of the adhesion-improving layer 60.

In the joined state, a combined bonding layer 45 is present (cf. FIG. 2b). With the aid of a low-temperature sintering method, the second bonding layer 41 and the adhesion-improving layer 60 are pressed together so that the combined bonding layer 45 is formed.

The large-area semiconductor element 90 is in turn applied with the aid of the contacting layer 50 onto the first side 21 of the first layer 20.

Also, in connection with the exemplary embodiment according to FIGS. 2a and 2b it is possible to see that the layer thickness d1 of the first layer 20 is multiple-times larger than the layer thickness d2 of the second layer 30 made from material M2 of low expandability. The layer thickness d1 of the first layer 20 is likewise larger than the layer thickness d3 of the third layer 25 made from the first material M1.

The second layer 30 made from second material M2 of low expandability is formed asymmetrically inside the layer stack. An asymmetric placement of the second layer 30 of low expandability has the advantage that an axis of symmetry results in a targeted manner from the expansion of the large-area semiconductor element 90, particularly the silicon semiconductor element, and the expansion of the coated substrate plate 10. A planar contour of the semiconductor module 100 can finally be achieved, depending on the thickness dHL of the large-area semiconductor element 90 by means of the position of the second layer 30 made from material M2 of low expandability after the cooling.

1-20. (canceled)

21. A method for producing a substrate plate for a large-area semiconductor element, comprising,
bonding together at least one first layer made from a first material, having a first coefficient of expansion and at least one second layer made from a second material of low expandability, having a second coefficient of expansion that is smaller than the first coefficient of expansion;
wherein the layers are bonded to one another by means of a low-temperature sintering method at a bonding temperature of 150° C.-300° C.; and
forming at least one first bonding layer made from a bonding material between the first layer and the second layer, and the bonding temperature substantially corresponds to a mounting temperature during the bonding of the substrate plate produced with at least one large-area semiconductor element.

22. The method of claim 21, wherein the bonding temperature is between 240° C.-260° C.

23. The method of claim 21, wherein the bonding material of the bonding layer creates a bond that withstands temperatures above the bonding temperature and has a diffusion metal comprising one of a group comprising silver (Ag), a silver alloy, gold (Au), a gold alloy, copper (Cu), and a copper alloy.

24. The method of claim 21, wherein the first material has metal comprising one of a group comprising copper (Cu) and a copper alloy, and the second material has a nickel alloy comprising one of a group comprising Invar (Fe₆₅Ni₃₅), Invar 36 (Fe₆₄Ni₃₆), Kovar (Fe₅₄Ni₂₉Co₁₇), tungsten (W), an iron-nickel-cobalt alloy (FeNiCo alloy), and molybdenum (Mo).

25. The method of claim 21, wherein the bonding at least of the first layer at least to the second layer and at least the first bonding layer takes place by means of the application of pressure between 10 MPa-28 MPa.

26. A substrate plate for a large-area semiconductor element, comprising:
at least one first layer made from a first material, having a first coefficient of expansion;
at least one second layer made from a second material of low expandability, having a second coefficient of expansion, which is smaller than the first coefficient of expansion; and
at least one first bonding layer formed between the first layer and the second layer, wherein the first bonding layer comprises diffusion metal comprising one of a group comprising silver (Ag), a silver alloy, gold (Au), a gold alloy, copper (Cu), and a copper alloy.

27. The substrate plate of claim 26, wherein at least the first bonding layer is formed as a boundary layer of the first layer or the second layer.

28. The substrate plate of claim 26, wherein the first material has metal comprising one of a group comprising copper (Cu) and a copper alloy and the second material comprises one of a group comprising a nickel alloy, Invar (Fe₆₅Ni₃₅), Invar 36 (Fe₆₄Ni₃₆), Kovar (FesaNi₂₉Co₁₇), tungsten (W), an iron-nickel-cobalt alloy (FeNiCo alloy), and molybdenum (Mo).

29. The substrate plate of claim 26, wherein at least one third layer comprises the first material, which is bonded by means of a second bonding layer comprising the bonding material, to the second layer comprising the second material of low expandability.

30. The substrate plate of claim 29, wherein at least one fourth layer comprising the second material, which is bonded by means of a third bonding layer comprising the bonding material, to the third layer comprising the first material.

31. The substrate plate of claim 29, wherein the individual layers and bonding layers are symmetrical arranged in such a manner that a flat substrate plate is formed.

32. The substrate plate of claim 29, wherein the individual layers and bonding layers are asymmetrical arranged in such a manner that a convexly or concavely shaped substrate plate is formed.

33. The substrate plate of claim 29, wherein the first layer, the second layer, and the third layer, have different layer thicknesses.

34. The substrate plate of claim 30, wherein the second layer and at least the fourth layer is embedded in a layer comprising the first material.

35. The substrate plate of claim 26, wherein the second layer and the first layer are formed in one of a frame-like, grid-like, and wire-like manner.

36. A method for producing a semiconductor module, comprising
forming a substrate plate, comprising:
bonding together at least one first layer made from a first material, having a first coefficient of expansion and at least one second layer made from a second material of low expandability, having a second coefficient of expansion that is smaller than the first coefficient of expansion;
wherein the layers are bonded to one another by means of a low-temperature sintering method at a bonding temperature of 150° C.-300° C.; and
forming at least one first bonding layer made from a bonding material between the first layer and the second layer, and the bonding temperature substantially corresponds to a mounting temperature during the bonding of the substrate plate produced with at least one large-area semiconductor element;
providing at least one large-area semiconductor element comprising one of a thyristor wafer and a diode; and
boding the large-area semiconductor element, by means of a contacting layer, to the substrate plate at a mounting temperature of 150° C.-300° C., wherein the mounting temperature substantially corresponds to the bonding temperature during the bonding of the layers of the substrate plate.

37. The method of claim 36, wherein the bonding of the layers of the substrate plate and the bonding of the large-area semiconductor element to the substrate plate take place simultaneously.

38. The method of claim 36, wherein the mounting temperature is between 240° C.-260° C.

39. A semiconductor module comprising:
a substrate plate, comprising:
at least one first layer made from a first material, having a first coefficient of expansion;
at least one second layer made from a second material of low expandability, having a second coefficient of expansion, which is smaller than the first coefficient of expansion; and
at least one first bonding layer formed between the first layer and the second layer, wherein the first bonding layer comprises diffusion metal comprising one of a group comprising silver (Ag), a silver alloy, gold (Au), a gold alloy, copper (Cu), and a copper alloy; and
at least one large-area semiconductor element comprising one of a thyristor wafer and a diode.

40. The semiconductor module of claim 39, wherein the large-area semiconductor element is bonded to the first layer of the substrate plate by means of a contacting layer.
